(19) United States
(12) Patent Application Publication
(10) Pub. No.: US 2007/0200187 A1
(43) Pub. Date: Aug. 30, 2007

(54) Nanowire device and method of making

(76) Inventors: Islamshah S. Amlani, Chandler, AZ (US); Pawitter S. Mangat, Gilbert, AZ (US)

Correspondence Address: INGRASSIA FISHER & LORENZ, P.C., 7150 E. CAMELBACK, STE. 325, SCOTTSDALE, AZ, 85251, US

(21) Appl. No.: 11/363,696

(22) Filed: Feb. 28, 2006

(51) Int. Cl. H01L 29/84; H01L 21/00

(52) U.S. Cl. 257/415; 438/700; 438/50; 977/887; 977/762

(57) ABSTRACT

A method (40) for fabricating a nanoscale device, includes nano-imprinting (44) a one dimensional nanostructure (20) on a material (12), forming (46) a patterning layer (22, 26) over the one dimensional nanostructure (20) and the material (12), patterning (48) the patterning layer (22, 26) to differentiate an area over the one dimensional nanostructure (20), and etching (52, 56) the differentiated area and a portion of the material (12) to create a trench (24) under the one dimensional nanostructure (20). The one dimensional nanostructure (20) is coupled to circuitry (30) formed in the material (12).

### FIELD OF THE INVENTION

The present invention generally relates to nanowire devices, and more particularly to a method of making a nanowire device applications such as sensing devices.

### BACKGROUND OF THE INVENTION

One-dimensional nanostructures, such as belts, rods, tubes and wires, have become the latest focus of intensive research with their own unique applications. One-dimensional nanostructures are model systems to investigate the dependence of electrical and thermal transport or mechanical properties as a function of size reduction. In contrast with zero-dimensional, e.g., quantum dots, and two-dimensional nanostructures, e.g., GaAs/AlGaAs superlattice, direct synthesis and growth of one-dimensional nanostructures has been relatively slow due to difficulties associated with controlling the chemical composition, dimensions, and morphology. Alternatively, various one-dimensional nanostructures have been fabricated using a number of advanced nanolithographic techniques, such as electron-beam (e-beam), focused-ion-beam (FIB) writing, and scanning probe.

One class of one-dimensional nanostructures is nanowires. Nanowires of inorganic materials have been grown from metal (Ag, Au), elemental semiconductors (e.g., Si, and Ge), III-V semiconductors (e.g., GaAs, GaN, GaP, InAs, and InP), II-VI semiconductors (e.g., CdS, CdSe, ZnS, and ZnSe) and oxides (e.g., SiO₂ and ZnO). Inorganic nanowires can be synthesized with various diameters and length, depending on the synthesis technique and/or desired application needs.

Nanowires have been demonstrated as field effect transistors (FETs) and other basic components in nanoscale electronic such as p-n junctions, bipolar junction transistors, inverters, etc.

Additionally, one dimensional nanostructures have been shown to be highly sensitive chemical and biological sensors. The utility of detecting the presence or absence of a specific agent is one type of known detection scheme. The extremely high surface-to-volume ratios associated with these nanostructures make their electrical properties extremely sensitive to species adsorbed on their surface. The surfaces of semiconductor nanowires have been modified and implemented as highly sensitive, real-time sensors for pH and biological species. For example, as the agent attaches itself to a one dimensional nanostructure, the measurable resistance of the one dimensional nanostructure changes. As the resistance changes, a quantitative result, e.g., concentration, may be determined. Known one dimensional nanostructure systems use a single one dimensional nanostructure (only one path for determining resistance), a random network, or an array of one dimensional nanostructure to determine the presence of an unwanted agent.

One known approach to manufacture nanowires is a top-down approach which uses e-beam lithography. However, this e-beam process is not desirable for mass production due its throughput limitations. Nanowire devices have also been fabricated by post synthesis assembly techniques, such as dispersion on an insulating substrate followed by patterning of electrodes on a few selected nanowires using lithography. Furthermore, nanowire synthesis methods typically, whether chemical vapor deposition or solution based, produce nanowires with a range of dimension and a range of properties. Conventional nanowire fabrication approaches include forming the nanowire using, for example, chemical vapor deposition (for crystalline semiconducting nanowires) or porous alumina membrane as a template (for metallic nanowires). Once the nanowires are fabricated, they are assembled on a substrate using either a random assembly approach or an ordered approach using micro fluidic channels for potential application.

Accordingly, it is desirable to provide a method for manufacturing a one dimensional nanostructure device. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for fabricating a nanoscale device, includes nano-imprinting a one dimensional nanostructure on a material, forming a patterning layer over the one dimensional nanostructure and the material, patterning the patterning layer to differentiate an area over the one dimensional nanostructure, and etching the differentiated area and a portion of the material to create a trench under the one dimensional nanostructure. The one dimensional nanostructure is coupled to circuitry formed in the material.

### BRIEF DESCRIPTION OF THE DRAWINGS

The present invention will hereinafter be described in conjunction with the following drawing figures, wherein like numerals denote like elements, and

FIGS. 1 and 2 are partial top views of an exemplary embodiment in progressive states of fabrication;

FIG. 3 is a partial side view taken along line 3-3 of FIG. 2;

FIG. 4 is a partial top view of another exemplary embodiment;

FIG. 5 is a partial side view taken along line 5-5 of FIG. 4;

FIG. 6 is a partial top view of yet another exemplary embodiment;

FIG. 7 is a flow chart of the first and second exemplary embodiments; and

FIG. 8 is a block diagram of a sensor system including one of the exemplary embodiments.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

When a molecule attaches itself to a nanostructure, e.g., a one dimensional nanostructure, a characteristic of the material changes, such as the change in a current flowing in the one dimensional nanostructure that is measurable. The sensing mechanism stems from changes in charge density on the surface of the nanostructure, thereby affecting the carrier concentration inside the nanostructure. While a nanowire is the preferred embodiment of the one dimensional nanostructure, other embodiments would include, and for the purposes of this patent be included within the definition of one dimensional nanostructure, all other nanostructures with a high aspect ratio (length versus width). One or more one dimensional nanostructures may also be fabricated as an interdigited device. Other exemplary embodiments may include free standing structures, such as a cantilever, an interdigited array, and a ring. Additionally, the one dimensional nanostructure may be coated with a substance (functionalized with molecule specific coating) for determining specific environmental agents. And while a change in current is the preferred embodiment for the measurable material characteristic, other embodiments would include, for example, magnetic, optical, frequency, and mechanical for measurable material characteristics.

By measuring this change in the current, it is known that a determination may be made as to the number of molecules that have attached to the one dimensional nanostructure, and therefore, a correlation to the concentration of the molecules in the environment around the one dimensional nanostructure. Known systems place an electrode across a one dimensional nanostructure to measure this change in the material characteristic.

As subsequently described in more detail, free standing nanowires are fabricated using nano-imprint lithography. The nanowires are pre-positioned in desired locations and, being free standing, provide a higher degree of sensitivity (due to increased surface area) for sensor applications. The diameter of the nanowire can be easily varied using the appropriate thickness of the top layer material and the nano-imprint template and can be as small as 5 nm.

Imprinting technologies are being pursued as an alternative approach for nanolithography. Unlike optical technologies, these imprinting techniques are based on contact printing, and therefore do not require expensive and complex optics and light sources for creating images. As a result, imprinting may offer the possibility of greater simplicity and lower cost for manufacturing sub-50 nm resolution nanowires. In the case of imprint lithography, the pattern to be imprinted is defined on a master template. In the case of this invention, the template will have features for the nanowire fabrication. During the imprint process, the substrates (wafers) to be patterned is first dispensed with an etch barrier on the wafer followed by an in-situ low pressure compression of the template to the etch barrier and ultra violet cure. The template is then release leaving the micro-molded pattern along with a residual layer several hundred angstroms thick. The left behind pattern is transferred onto the underlying predefined films such as oxides or nitrides on substrate (such as silicon or quartz, for example).

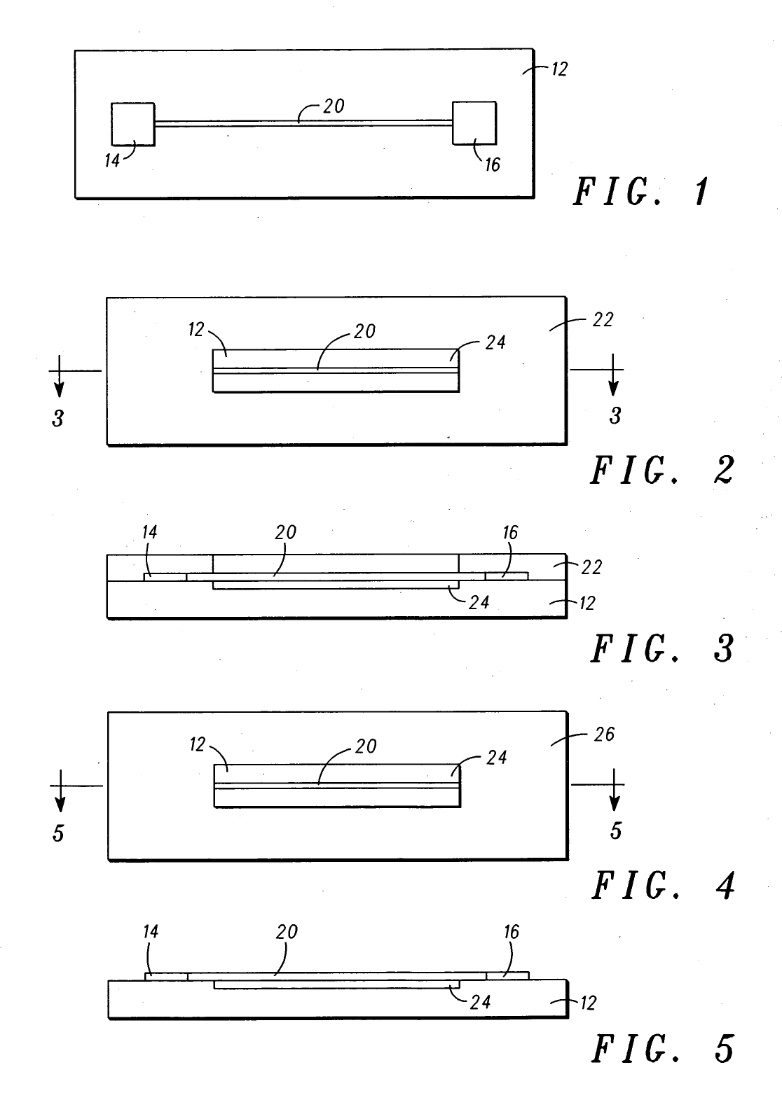

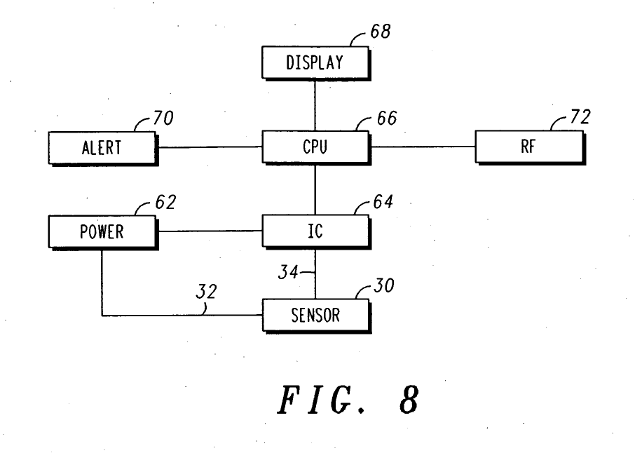

FIG. 1 shows a nanowire device fabricated using an imprint process. The substrate 12 preferably comprises silicon; however, alternate materials, for example, quartz, sapphire, plastic, ceramic, metal, other semiconductor materials, or a flexible material are anticipated by this disclosure. Substrate 12 may include control electronics or other circuitry, some of which may comprise circuitry shown in FIG. 8. Also, substrate 12 may include an insulating layer, such as silicon dioxide, silicon nitride, or the like.

The nanowire 20 is nano-imprinted on the substrate 12. Optionally, the nanowire 20 and the pads 14 and 16 use an imprint template having desired dimensions mounted on an imprint tool. FIG. 1 highlights an exemplary imprint of the nanaowire 20 and, optionally, the pads 14 and 16 on the substrate needed for device fabrication. The nano-imprinting process may include a deposition process on the imprint substrate such as sputter, lift-off, chemical vapor deposition, or atomic layer deposition.

Pads 14 and 16, alternatively, may subsequently be formed using other forms of lithography. The pads 14 and 16 comprise Ti/Au, but may comprise any conducting material. The pads 14 and 16 are preferably spaced between 10 nanometers and 1 millimeters apart. The thickness of the pads 14 and 16 is generally between 0.01 and 100 micrometers, and would preferably be 1.0 micrometer.

Although only one method of one dimensional nanostructure growth is disclosed above, the nanowire 20 may be grown using a lift-off process in any manner known to those skilled in the art, and are typically 10 nm to 1 cm in length and less than 1 nm to 100 nm in thickness. It should be noted the nanowire may have varying thickness and height, forming different shapes, for example, elliptical or rectangular. Contact between the nanowire 20 and electrodes 14 and 16 is made during fabrication, for example, by any type of lithography, e-beam, optical, soft lithography, or nano-imprint technology.

Once the nanowire 20 is placed between the pads 14 and 16, a dielectric layer 22 is deposited over the nanowire 20, pads 14 and 16, and substrate 12. The dielectric layer 22 preferably comprises silicon dioxide, but may comprise any type of dielectric material. The dielectric layer 22 is then patterned and etched, with the etch cutting into the substrate 12 underneath the nanowire 20, thereby creating a trench 24, to expose the nanowire as shown in FIGS. 2 and 3. The nanowire 20 is therefore freestanding, with the outer surface 360 degrees around exposed to the environment.

Referring to FIGS. 4 and 5, another exemplary embodiment comprising placing a photoresist 26 over the nanowire 20, pads 14 and 16, and substrate 12 (at least in the area of the nanowire 20). The photoresist 26 is patterned and the portion above the nanowire 20 is removed. An etch is then selectively performed to create the trench 24 underneath the nanowire 20 to expose the nanowire and the photoresist 26 is removed (FIG. 5). The nanowire 20 is therefore freestanding, with the outer surface 360 degrees around exposed to the environment.

Referring to FIG. 6, another exemplary embodiment of the present invention comprises a device 30 including a first electrode 32 and a second electrode 34. The first electrode 32 is coupled to one or more pads 14 and the second electrode 34 is coupled to one or more pads 16. The electrodes 32 and 34 may be further coupled to circuit elements (not shown) on the substrate on the same layer or to on other layers by a via.

It should be understood that while one or two nanowires 20 are illustrated in the exemplary embodiments described herein, many hundreds or thousands may exist in arbitrary orientation on a single substrate. Additionally, while only one nanowire 20 is shown between each of the pads 14 and 16, more than one nanowire 20 may be formed between the pads 14 and 16.

An optional electropolishing step may be used to smooth the nanowire for some applications.

For chemical or biological sensor applications, the one dimensional nanostructure 20 may be either chemically functionalized or coated to provide better selectivity and/or sensitivity to a particular environmental agent.

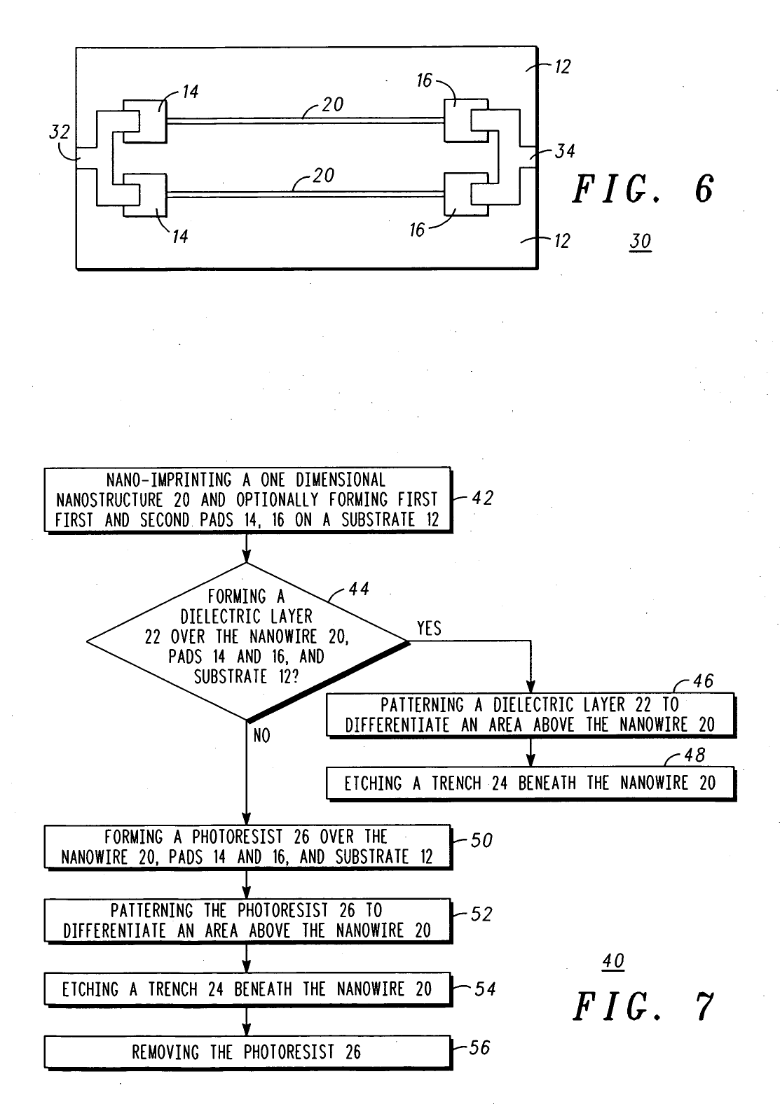

A flow chart of the process 40 to create the exemplary embodiments described herein is shown in FIG. 7 and comprises nano-imprinting 42 a one dimensional nanostructure 20 and optionally forming first and second pads 14, 16 on the substrate 12. A dielectric layer 22 may be formed 44 over the nanowire 20, pads 14 and 16, and substrate 12. If so, the dielectric layer 22 is patterned 46 to differentiate an area over the nanowire 20. Then, the trench 24 beneath the nanowire 20 is etched 48. If the photoresist 26 was formed 50, the photoresist 26 is patterned 52 to define an area above the nanowire 20. The trench 24 is etched 52 beneath the nanowire 20, and the photoresist is removed 54.

Referring to FIG. 8, an exemplary system 60 includes the device 30, for example, having its electrodes 32 and 34 coupled to a power source 62, e.g., a battery. A circuit 64 determines the current between the electrodes and supplies the information to a processor 66. The information may be transferred from the processor 66 to a display 68, an alert device 70, or an RF transmitter 72.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A method comprising:
nano-imprinting a one dimensional nanostructure on a material;
forming a patterning layer over the one dimensional nanostructure and the material;
patterning the patterning layer to differentiate an area over the one dimensional nanostructure; and
etching the differentiated area and a portion of the material to create a trench under the one dimensional nanostructure.

2. The method of claim 1 wherein the nano-imprinting step comprises one of a subtractive process or a lift-off process.

3. The method of claim 1 wherein the forming step comprises forming a dielectric layer.

4. The method of claim 1 wherein the forming step comprises forming a photoresist layer.

5. The method of claim 4 further comprising removing the photoresist layer.

6. The method of claim 1 wherein the nano-imprinting step comprises nano-imprinting first and second conductive pads at opposed ends of the one dimensional nanostructure.

7. The method of claim 1 further comprising:
forming a first electrode coupled to the first conductive pad;
forming a second electrode coupled to the second conductive pad; and
forming circuit elements coupled to the first and second electrode for sensing environmental agents attaching to the one dimensional nanostructure.

8. The method of claim 1 wherein the nano-imprinting step comprises nano-imprinting one of a nanowire, a cantilever, an interdigited array, and a ring.

9. The method of claim 1 further comprising electropolishing the one dimensional nanostructure.

10. A method for fabricating a sensor in an integrated circuit, comprising:
providing a substrate;
forming a sensor circuit over the substrate;
nano-imprinting a nanowire over the substrate;
forming a patterning layer over the one dimensional nanostructure and the material;
patterning the patterning layer to differentiate an area over the one dimensional nanostructure;
etching the differentiated area and a portion of the substrate to create a trench under the one dimensional nanostructure; and
coupling the nanowire to the sensor circuit.

11. The method of claim 10 wherein the nano-imprinting step comprises one of a subtractive process or a lift-off process.

12. The method of claim 10 wherein forming a patterning layer comprises forming a dielectric layer.

13. The method of claim 10 wherein the forming a patterning layer comprises forming a photoresist layer.

14. The method of claim 13 further comprising removing the photoresist layer.

15. The method of claim 10 wherein the nano-imprinting step comprises nano-imprinting first and second conductive pads at opposed ends of the one dimensional nanostructure.

16. The method of claim 10 further comprising:
forming a first electrode coupled to the first conductive pad;
forming a second electrode coupled to the second conductive pad; and
forming circuit elements coupled to the first and second electrode for sensing environmental agents attaching to the one dimensional nanostructure.

17. The method of claim 10 wherein the nano-imprinting step comprises nano-imprinting one of a nanowire, a cantilever, an interdigited array, and a ring.

18. The method of claim 10 further comprising electropolishing the one dimensional nanostructure.

19. A device comprising:
a material defining a trench; and
an electronic circuit formed in the material, the electronic circuit comprising:
a one dimensional nanostructure nano-imprinted on the material and suspended over the trench.

20. The device of claim 19 further comprising a dielectric layer overlying the one dimensional nanostructure and at least a portion of the material.
